(19) United States
(12) Patent Application Publication
(10) Pub. No.: US 2026/0169204 A1
(43) Pub. Date: Jun. 18, 2026

(54) GRATING STRUCTURE CAPABLE OF GENERATING SPACE-TIME VORTEX LIGHT AND PREPARATION METHOD THEREOF

(71) Applicant: Anhui University, Hefei City (CN)

(72) Inventors: Ming Fang, Hefei City (CN); Jun Fu, Hefei City (CN); Haojun Jiang, Hefei City (CN); Mandi Rong, Hefei City (CN); Jian Feng, Hefei City (CN); Ke Xu, Hefei City (CN); Xuesong Deng, Hefei City (CN); Zhixiang Huang, Hefei City (CN); Xianliang Wu, Hefei City (CN)

(21) Appl. No.: 19/279,561

(22) Filed: Jul. 24, 2025

(30) Foreign Application Priority Data
Dec. 12, 2024 (CN) 202411825053.7

(51) Int. Cl. G02B 5/18; C23C 14/18; C23C 14/28; C23C 16/24; C23C 16/50; C23C 16/56; C23C 28/00; G03F 1/20; G03F 7/00; G03F 7/09; G03F 7/16

(52) U.S. Cl. CPC G02B 5/1857; C23C 14/18; C23C 14/28; C23C 16/24; C23C 16/50; C23C 16/56; C23C 28/322; C23C 28/34; G03F 1/20; G03F 7/0035; G03F 7/093; G03F 7/168; G03F 7/70383

(57) ABSTRACT

A grating structure capable of generating space-time vortex light and a preparation method thereof are provided. The grating structure is composed of multiple one-dimensional photonic crystal cells arranged periodically. The one-dimensional photonic crystal cell includes a high Si grating, a short Si grating and a SiO₂ substrate, where the high Si grating and the short Si grating are arranged on the SiO₂ substrate. Cross sections of the high Si grating and the short Si grating are both rectangular. A length of the one-dimensional photonic crystal cell is 400 nanometers (nm), a height of the high Si grating is 150 nm, a height of the short Si grating is 55 nm, and an interval between the high Si grating and the short Si grating is 50 nm.

### CROSS-REFERENCE TO RELATED APPLICATIONS

This application claims priority to Chinese Patent Application No. 202411825053.7, filed on Dec. 12, 2024, the contents of which are hereby incorporated by reference.

### TECHNICAL FIELD

The disclosure belongs to the technical field of nano gratings, and in particular to a grating structure capable of generating space-time vortex light and a preparation method thereof.

### BACKGROUND

Space-time optical vortex is a new type of optical vortex, which has the characteristic of carrying transverse orbital angular momentum, and this makes it show novel characteristics in optical phenomena and has attracted much attention in recent years. Its characteristic of carrying transverse orbital angular momentum provides additional degrees of freedom for the manipulation of light, which is of great significance to the space-time control of light-matter interaction. Unfortunately, the existing methods for generating space-time optical vortices are plagued by various limitations, such as inefficiency, huge volume and complexity. In terms of cost, the existing equipment, such as 4f pulse shaper, needs many high-precision gratings, lenses and phase plate, resulting in high manufacturing costs for each component. Additionally, the equipment requires debugging by professionals, leading to high labor costs. The scheme of generating space-time optical vortices by nonlinear photonic crystals requires high-purity materials, complex technological processes and sophisticated equipment. In terms of size and integration, the pulse shaper based on Fourier transform, composed of many optical elements such as gratings, needs more floor space, which is not conducive to integration into small and micro devices, such as structured optical communication and quantum information processing equipment. Therefore, it is necessary to develop space-time optical vortex generation equipment with small size, low manufacturing cost and simple use to meet different application requirements.

### SUMMARY

The disclosure aims at solving the shortcomings of the prior art, and provides a grating structure capable of generating space-time vortex light and a preparation method thereof. The prepared grating structure may generate space-time optical vortices simply and conveniently without complex optical lens combination.

In order to achieve the above objectives, the present disclosure provides the following schemes:
a grating structure capable of generating space-time vortex light, where the grating structure is composed of a plurality of one-dimensional photonic crystal cells arranged periodically; and
the one-dimensional photonic crystal cell includes a high Si grating, a short Si grating and a SiO₂ substrate, where the high Si grating and the short Si grating are arranged on the SiO₂ substrate.

Optionally, cross sections of the high Si grating and the short Si grating are both rectangular.

Optionally, a length of the one-dimensional photonic crystal cell is 400 nanometers (nm), a height of the high Si grating is 150 nm, a height of the short Si grating is 55 nm, and an interval between the high Si grating and the short Si grating is 50 nm.

The disclosure also provides a method for preparing a grating structure capable of generating space-time vortex light, where the preparation method is used for preparing the grating structure described in any one of the above, including following steps:
S1, depositing a layer of amorphous silicon with a thickness of 150 nm on a molten silicon substrate with a thickness of 500 micrometers (μm) by using plasma enhanced chemical vapor deposition to obtain an amorphous silicon film, and cleaning a surface of the amorphous silicon film by using oxygen plasma;
S2, coating a positive electron beam resist on the amorphous silicon film by dynamic gluing, performing soft baking after gluing to remove a solvent of the positive electron beam resist, and then coating an anti-charging conductive polymer on a surface of the positive electron beam resist by the dynamic gluing again, and performing the soft baking again;
S3, photoetching the high Si grating on the surface of the positive electron beam resist by using a high-energy accelerated electron beam, developing in ethyl acetate, depositing an aluminum layer on the surface of the positive electron beam resist by using an electron beam evaporator to obtain an aluminum mask, and then stripping the positive electron beam resist by using N-methylpyrrolidone;
S4, adopting CF₄ to carry out reactive ion etching, and transferring a pattern of the aluminum mask to the amorphous silicon film;
S5, removing the residual aluminum mask with an aluminum etchant, and then repeating the S2;
S6, repeating the S3, and exposing and photoetching the high Si grating and the short Si grating;
S7, repeating the S4, transferring the pattern of the aluminum mask to the amorphous silicon film, and photoetching the interval between the high Si grating and the short Si grating;
S8, cleaning the aluminum mask with the aluminum etchant to obtain the one-dimensional photonic crystal cell; and
S9, periodically arranging a plurality of the one-dimensional photonic crystal cells to obtain the grating structure.

Optionally, a method for coating the positive electron beam resist includes: coating a 200 nm thick resist on the amorphous silicon film at a rotation speed of 4000 revolutions per minute (rpm), and baking at 180 degrees Celsius (° C.) for 3 minutes.

Optionally, a method for coating the anti-charging conductive polymer includes: coating the anti-charging conductive polymer on the surface of the positive electron beam resist at a rotating speed of 4000 rpm, and baking at 90° C. for 90 seconds.

Compared with the prior art, the disclosure has the following beneficial effects.

The disclosure includes a group of one-dimensional photonic crystal cells formed by two Si gratings, one high and one short, and a SiO₂ substrate, which are periodically repeated to form the grating structure. By adopting the technical schemes of the disclosure, the passing femtosecond laser pulse may generate a space-time optical vortex without passing through multiple optical components, thereby effectively reducing the volume of equipment.

### BRIEF DESCRIPTION OF THE DRAWINGS

In order to explain the technical scheme of the present disclosure more clearly, the drawings needed in the embodiments are briefly introduced below. Obviously, the drawings in the following description are only some embodiments of the present disclosure. For ordinary people in the field, other drawings may be obtained according to these drawings without paying creative labor.

FIG. 1 is a schematic diagram of a grating structure according to an embodiment of the present disclosure.

FIG. 2 is a schematic diagram of a one-dimensional photonic crystal cell structure according to an embodiment of the present disclosure.

FIG. 3A and FIG. 3B are schematic diagrams of the simulation structure according to Embodiment 4 of the present disclosure, where FIG. 3A is a schematic diagram of four ports in a resonance mode, and FIG. 3B is a schematic diagram of a single cell model in the simulation.

FIG. 4 is a flow chart of a method for preparing a grating structure capable of generating space-time vortex light.

FIG. 5 is a flow chart of the specific steps of simulation by using COMSOL in Embodiment 4.

### DETAILED DESCRIPTION OF THE EMBODIMENTS

In the following, the technical schemes in the embodiment of the disclosure will be clearly and completely described with reference to the attached drawings. Obviously, the described embodiments are only a part of the embodiments of the disclosure, but not the whole embodiments. Based on the embodiments in the present disclosure, all other embodiments obtained by ordinary technicians in the field without creative labor belong to the scope of protection of the present disclosure.

In order to make the above objects, features and advantages of the present disclosure more obvious and easy to understand, the present disclosure will be further described in detail with the attached drawings and specific embodiments.

### Embodiment 1

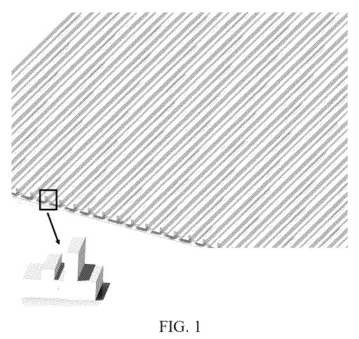

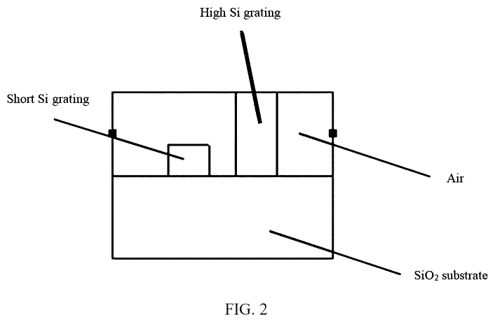

In this embodiment, a grating structure capable of generating space-time vortex light is composed of multiple one-dimensional photonic crystal cells arranged periodically, as shown in FIG. 1. The one-dimensional photonic crystal cell, as shown in FIG. 2, includes a high Si grating, a short Si grating and a SiO₂ substrate, where the high Si grating and the short Si grating are arranged on the SiO₂ substrate. Cross sections of the high Si grating and the short Si grating are both rectangular. A length of the one-dimensional photonic crystal cell is 400 nanometers (nm), a height of the high Si grating is 150 nm, a height of the short Si grating is 55 nm, and an interval between the high Si grating and the short Si grating is 50 nm.

### Embodiment 2

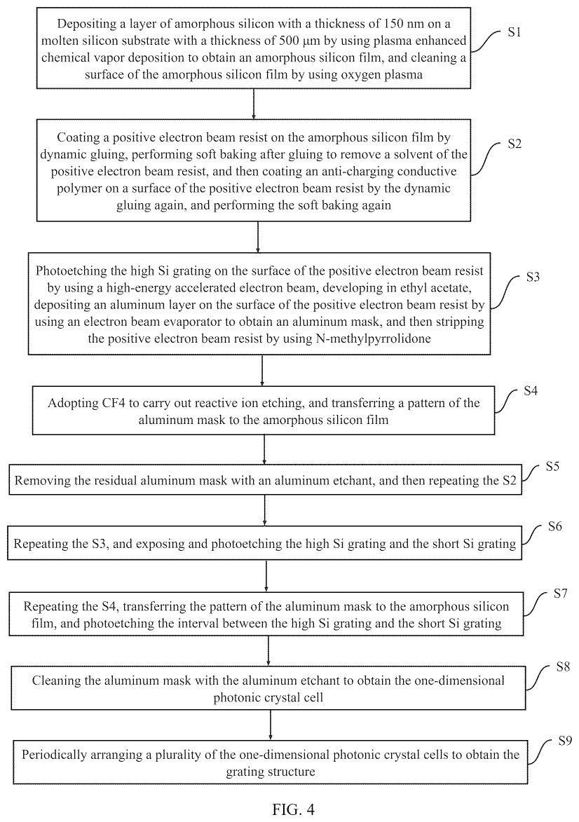

As shown in FIG. 4, in this embodiment, a method for preparing a grating structure capable of generating space-time vortex light includes the following steps:
S1, depositing a layer of amorphous silicon with a thickness of 150 nm on a molten silicon substrate with a thickness of 500 micrometers (μm) by using plasma enhanced chemical vapor deposition to obtain an amorphous silicon film, and cleaning a surface of the amorphous silicon film by using oxygen plasma;
S2, coating a positive electron beam resist on the amorphous silicon film by dynamic gluing, specifically, coating a 200 nm thick resist on the amorphous silicon film at a rotation speed of 4000 revolutions per minute (rpm), and performing soft baking after gluing to remove a solvent of the positive electron beam resist to enhance its adhesion, specifically, baking at 180 degrees Celsius (° C.) for 3 minutes; and reducing the charging effect during electron beam photoetching by dynamically coating an anti-charging conductive polymer on the surface of the positive electron beam resist, specifically, coating the anti-charging conductive polymer on the surface of the positive electron beam resist at a rotating speed of 4000 rpm, and performing the soft baking again, specifically, baking at 90° C. for 90 seconds;
S3, photoetching a high Si grating on the surface of the positive electron beam resist by using a 30 kiloelectronvolt (keV) high-energy accelerated electron beam, developing the grating in ethyl acetate, and then depositing an aluminum layer with a thickness of 30 nm on the surface of the positive electron beam resist by using an electron beam evaporator to obtain an aluminum mask for protecting the high Si grating part; and then stripping the positive electron beam resist by using N-methylpyrrolidone;
S4, adopting CF₄ to carry out reactive ion etching, and transferring a pattern of the aluminum mask to the amorphous silicon film, specifically, using optical emission spectroscopy to track the etching process in real time during the etching process to ensure that the etched amorphous silicon has a thickness of 55 nm;
S5, removing the residual aluminum mask with an aluminum etchant, and then repeating the S2;
S6, repeating the S3, and exposing and photoetching the high Si grating and the short Si grating to ensure that the aluminum mask deposited subsequently may protect the etched grating;
S7, repeating the S4, transferring the pattern of the aluminum mask to the amorphous silicon film, and photoetching the interval between the high Si grating and the short Si grating;
S8, cleaning the aluminum mask with the aluminum etchant to obtain the one-dimensional photonic crystal cell; and
S9, periodically arranging multiple the one-dimensional photonic crystal cells to obtain the grating structure; and in this embodiment, periodically arranging 2500 one-dimensional photonic crystal cells in the transverse direction and directly stretching the cells in the longitudinal direction to obtain a grating with a specification of 1 millimeter (mm)×1 mm, as shown in FIG. 1.

### Embodiment 3

In this embodiment, when the grating structure works, the intrinsic topological singularity induced by the C₂ symmetry and z-mirror symmetry breaking of the nano grating is utilized to Fourier transform the spiral phase in the momentum-frequency space to generate space-time optical vortices in the time-space domain. When the laser pulse passes through the nano grating, a part of the wavefront of the incident pulse is changed by the dispersion relation of optical resonance. Specifically, the interaction between pulse and nano grating may be divided into two processes: the first part of pulse energy is transmitted directly through nano grating, and does not interact with resonance mode; and the second part excites resonance and radiates outward, which will theoretically produce two different resonance interactions at ±kx. Then the characteristics of the whole transmitted light field g(ω, kₓ) in frequency-momentum space may be transferred to the finally observed pulse g(τ, x) in time-space domain, where ω represents the angular frequency of the incident pulse light, kₓ represents the wave vector, t represents the time, and x represents the one-dimensional space coordinate. Through two interleaved Fourier transform relations, the far field expression g(τ, x)={g(ω, kₓ)} is obtained. This demonstrates that a field with a spiral phase in the ω-kₓ domain may be converted into a field with a spiral phase in the τ-x domain, thereby generating the desired space-time vortex light.

Nano grating refers to the grating with nano-scale periodic structure, which may produce optical phenomena such as diffraction and interference when light waves pass through, thus realizing the manipulation of light waves. The working principle of nano grating is based on the diffraction and interference principle of light, and the light wave is modulated by periodic structure. In this embodiment, by manipulating the heights of two Si gratings, one high and one short, the frequency corresponding to the spiral phase center may be changed, and then a space-time vortex may be generated for light with different wavelengths. This is because changing the height of grating may change the overall symmetry, and the generation of space-time vortex light is related to the symmetry of grating.

According to the embodiment of the disclosure, by manipulating the symmetry of the gratings, that is, the heights of the two Si gratings, the incident laser pulse interacts with the resonance mode, thereby generating space-time vortex light. The simulation results show that the complex transmission coefficient of the system produces spiral phase and zero singularity in ω-kₓ domain. Because the electromagnetic field is invalid in the vortex center and the transmission coefficient reflects the characteristics of the emergent electromagnetic field, the field with spiral phase in ω-kₓ domain may be transformed into the field with spiral phase in τ-x domain, which indicates that the emergent electromagnetic field also has spiral phase and zero singularity in τ-x domain, that is, the required space-time vortex light.

### Embodiment 4

In this embodiment, the theoretical derivation of generating space-time vortex light will be given.

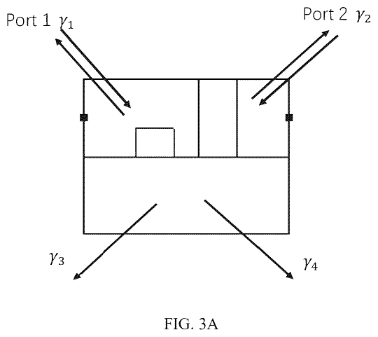

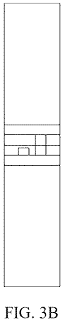

The interaction between pulse and nano grating may be divided into two processes: the first part of pulse energy is transmitted directly through nano grating, and does not interact with resonance mode; and the second part excites resonance and radiates outward. Theoretically, there will be two different resonance interactions at ±kx, including four ports, as shown in FIG. 3A, and the leakage rates are denoted as γ₁, γ₂, γ₃ and γ₄.

The transmission coefficient s is expressed as a complex number:

$$s = Re ( s ) + j Im ( s ) ,$$

$$Re ( s ) = \frac{( {γ}_{2} + {γ}_{4} ) [ - t ( ω - {ω}_{0} ) \pm \sqrt{4 {r}^{2} {t}^{2} {γ}_{2} {γ}_{4} - {( {γ}_{1} - {r}^{2} {γ}_{2} - {t}^{2} {γ}_{4} )}^{2}} / t ]}{{( ω - {ω}_{0} )}^{2} + {( {γ}_{2} + {γ}_{4} )}^{2}} + \frac{( ω - {ω}_{0} ) [ t ( {γ}_{2} - {γ}_{4} ) - ( {γ}_{1} - {r}^{2} {γ}_{2} - {t}^{2} {γ}_{4} ) / t ]}{{( ω - {ω}_{0} )}^{2} + {( {r}_{2} + {r}_{4} )}^{2}} ,$$

$$Im ( s ) = \frac{( ω - {ω}_{0} ) [ t ( {γ}_{2} - {γ}_{4} ) - ( {γ}_{1} - {r}^{2} {γ}_{2} - {t}^{2} {γ}_{4} ) / t ]}{{( ω - {ω}_{0} )}^{2} + {( {γ}_{2} + {γ}_{4} )}^{2}} + \frac{( ω - {ω}_{0} ) [ - t ( ω - {ω}_{0} ) \pm \sqrt{4 {r}^{2} {t}^{2} {γ}_{2} {γ}_{4} - {( {γ}_{1} - {r}^{2} {γ}_{2} - {t}^{2} {γ}_{4} )}^{2}} / t ]}{{( ω - {ω}_{0} )}^{2} + {( {γ}_{2} + {γ}_{4} )}^{2}} ,$$

where Re(s) represents the real part of the transmission coefficient, Im(s) represents the imaginary part of the transmission coefficient, r represents the reflection coefficient, t represents the transmission coefficient, and r²+t²=1 is satisfied, and do represents the resonance frequency.

The obtained phase q is:

$$φ ( s ) = arctan \frac{Im ( s )}{Re ( s )} .$$

In this embodiment, the two-dimensional frequency-momentum domain is focused on, when kₓ and ω change from P¹ to P², the phase w accumulated in the complex plane [Re(s), Im(s)] along the path P¹→P² may be expressed as:

$$Ψ = {\int }_{φ [ s ( {P}^{1} ) ]}^{φ [ s ( {P}^{2} ) ]} dφ .$$

In the ω-kₓ domain, the transmission coefficient s is eliminated at the winding center of the phase spiral, that is:

$$s ( {P}^{s} ) = Re [ s ( {P}^{s} ) ] + j Im [ s ( {P}^{s} ) ] = 0.$$

The point P^{s} that meets this condition is called zero singularity. If there is an isolated singularity P^{s}, the phase accumulation along any closed path around P^{s} is 2π, and the number of laps around the path is:

$$l = \frac{Ψ}{2 π} = - 1.$$

Therefore, the zero singularity shows topological charge 1=−1 in the transmission of grating. Combined with the above formula, the conditions satisfied by the zero singularity in the ω-kₓ domain may be determined by solving Re[s(P^{s})]=Im [s(P^{s})]=0:

$$\{ \begin{matrix}{( ω - {ω}_{0} )}^{2} = \frac{4 {r}^{2} {γ}_{2} {γ}_{4}}{{t}^{2}} - {( {γ}_{2} - {γ}_{4} )}^{2} \\ {γ}_{1} = {γ}_{2} \\ t \neq 0\end{matrix} .$$

In addition, in order to produce space-time optical vortex, the zero singularity of transmission parameters must be isolated, so as to meet the requirements of “hollow light intensity and spiral phase” of space-time optical vortex. In order to achieve this, the disclosure breaks C₂ symmetry and z-mirror symmetry in the plane, which makes γ₁=γ₂ not always true, and then introduces two degrees of freedom to the singularity of transmission coefficient, so only one singularity may be found in the ω-kₓ domain, which is the required space-time optical vortex.

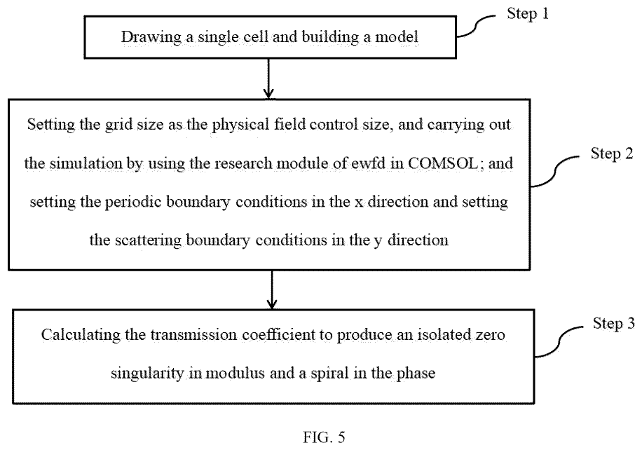

As shown in FIG. 5, in this embodiment, COMSOL is used for simulation, and the specific steps are as follows.

Step 1: drawing a single cell and building a model, as shown in FIG. 3B, where the models are air layer, air layer (for integral calculation), Si grating, SiO₂ substrate (for integral calculation) and SiO₂ substrate from top to bottom. Specific parameters are shown in Table 1.

TABLE 1

| Name | Expression | Size | Remarks |
|---|---|---|---|
| a1 | 252 [nm] | 2.52 × 10⁻⁷ | Center distance of Si grating |
| | | meters (m) | between adjacent cells |
| a2 | 148 [nm] | 1.48 × 10⁻⁷ m | Total width of two Si gratings (the |
| | | | width of a single grating is a2/2) |
| d | 150 [nm] | 1.5 × 10⁻⁷ m | Height of high Si grating |
| d1 | 55 [nm] | 5.5 × 10⁻⁷ m | Height of short Si grating |
| n1 | 1 | 1 | Low refractive index substrate and |
| | | | air refractive index |
| n2 | 3.72 | 3.72 | Si grating refractive index |
| a | a1 + a2 | 4 × 10⁻⁷ m | Periodic unit length |

Step 2: setting the grid size as the physical field control size, and carrying out the simulation by using the research module of Electromagnetic Wave and Frequency Domain (ewfd) in COMSOL; and setting the periodic boundary conditions in the x direction and setting the scattering boundary conditions in the y direction.

Step 3: calculating the transmission coefficient to produce an isolated zero singularity in modulus and a spiral in the phase.

The above embodiments only describe the optional mode of the disclosure, and do not limit the scope of the disclosure. Under the premise of not departing from the design spirit of the disclosure, various modifications and improvements made by ordinary technicians in the field to the technical schemes of the disclosure shall fall within the protection scope determined by the claims of the disclosure.

What is claimed is:

1. A grating structure capable of generating space-time vortex light, wherein the grating structure is composed of a plurality of one-dimensional photonic crystal cells arranged periodically; and
the one-dimensional photonic crystal cell comprises a high Si grating, a short Si grating and a SiO₂ substrate, wherein the high Si grating and the short Si grating are arranged on the SiO₂ substrate.

2. The grating structure capable of generating the space-time vortex light according to claim 1, wherein cross sections of the high Si grating and the short Si grating are both rectangular.

3. The grating structure capable of generating the space-time vortex light according to claim 1, wherein a length of the one-dimensional photonic crystal cell is 400 nm, a height of the high Si grating is 150 nm, a height of the short Si grating is 55 nm, and an interval between the high Si grating and the short Si grating is 50 nm.

4. A method for preparing a grating structure capable of generating space-time vortex light, wherein the method is used for preparing the grating structure according to claim 1, comprising following steps:
S1, depositing a layer of amorphous silicon with a thickness of 150 nm on a molten silicon substrate with a thickness of 500 μm by using plasma enhanced chemical vapor deposition to obtain an amorphous silicon film, and cleaning a surface of the amorphous silicon film by using oxygen plasma;
S2, coating a positive electron beam resist on the amorphous silicon film by dynamic gluing, performing soft baking after gluing to remove a solvent of the positive electron beam resist, and then coating an anti-charging conductive polymer on a surface of the positive electron beam resist by the dynamic gluing again, and performing the soft baking again;
S3, photoetching the high Si grating on the surface of the positive electron beam resist by using a high-energy accelerated electron beam, developing in ethyl acetate, depositing an aluminum layer on the surface of the positive electron beam resist by using an electron beam evaporator to obtain an aluminum mask, and then stripping the positive electron beam resist by using N-methylpyrrolidone;
S4, adopting CF₄ to carry out reactive ion etching, and transferring a pattern of the aluminum mask to the amorphous silicon film;
S5, removing the residual aluminum mask with an aluminum etchant, and then repeating the step S2;
S6, repeating the step S3, and exposing and photoetching the high Si grating and the short Si grating;
S7, repeating the step S4, transferring the pattern of the aluminum mask to the amorphous silicon film, and photoetching an interval between the high Si grating and the short Si grating;
S8, cleaning the aluminum mask with the aluminum etchant to obtain the one-dimensional photonic crystal cell; and
S9, periodically arranging a plurality of the one-dimensional photonic crystal cells to obtain the grating structure.

5. The method for preparing the grating structure capable of generating the space-time vortex light according to claim 4, wherein a method for coating the positive electron beam resist comprises: coating a 200 nm thick resist on the amorphous silicon film at a rotation speed of 4000 rpm, and baking at 180° C. for 3 minutes.

6. The method for preparing the grating structure capable of generating the space-time vortex light according to claim 4, wherein a method for coating the anti-charging conductive polymer comprises: coating the anti-charging conductive polymer on the surface of the positive electron beam resist at a rotating speed of 4000 rpm, and baking at 90° C. for 90 seconds.
